(19) United States
(12) Patent Application Publication
(10) Pub. No.: US 2005/0088829 A1
(43) Pub. Date: Apr. 28, 2005

(54) IC card-connecting adaptor

(75) Inventor: Minoru Igarashi, Tokyo (JP)

Correspondence Address: Finnegan, Henderson, Farabow,;Garrett & Dunner, L.L.P., 1300 I Street, N.W., Washington, DC, 20005-3315, US

(73) Assignee: YAMAICHI ELECTRONICS CO., LTD.

(21) Appl. No.: 10/972,653

(22) Filed: Oct. 26, 2004

(30) Foreign Application Priority Data
Oct. 27, 2003 (JP) 2003-366590

(51) Int. Cl. H05K 1/14

(52) U.S. Cl. 361/737

(57) ABSTRACT

Contact terminals, each having a contact pad section and a card-connecting end portion, are arranged in a connecting end unit portion.

This application claims priority from Japanese Patent Application No. 2003-366590 filed Oct. 27, 2003, which is incorporated hereinto by reference.

### BACKGROUND OF THE INVENTION

1. Field of the Invention

The present invention relates to an IC card-connecting adapter interposed between a predetermined IC card and a signal input/output section of an electronic apparatus, capable of electrically connecting the IC card to the signal input/output section.

2. Description of the Related Art

In the electronic apparatus such as a portable telephone, various functions are expanded thereto by connecting, via a card connector, an IC card, such as an SD (secure digital) card or a MEMORYSTICK (trademark), incorporating therein a central processing unit (CPU) or an integrated circuit for memory. Such an IC card is liable to be thinner and smaller in size as the portable telephone becomes thinner.

When it is desired to mount the IC card smaller in size than the existing one to the card connector or a card slot of the electronic apparatus designed to directly mount the existing IC card, the use of an adapter for connecting the IC card is proposed, for example, as shown in Japanese Patent Application Laid-open Nos. 2002-157056 and 2001-237027. This IC card-connecting adapter includes a slot connector section directly coupled to a card slot of the electronic apparatus and a card connector section electrically connected to an electrode section of the accommodated IC card, for example. The slot connector section is electrically connected to the card connector section via a predetermined wiring board disposed in the IC card-connecting adapter.

When the slot connector section and the card connector section are connected to each other via the wiring board as described above, a troublesome operation is necessary for connecting the wiring board to the slot connector section or the card connector section by the soldering in the assembly of the IC card connecting adapter. Accordingly, it is desired to save the soldering operation as much as possible during the assembly of the IC card-connecting adapter for the purpose of facilitating the high efficiency of the productivity.

### SUMMARY OF THE INVENTION

To solve the above-mentioned problems, an object of the present invention is to provide an IC card-connecting adapter interposed between a predetermined IC card and a signal input/output section of an electronic apparatus, for electrically connecting the IC card to the signal input/output section, in which the soldering operation can be eliminated during the assembly of the adapter.

To achieve the object, the inventive IC card-connecting adapter comprises a housing member forming an accommodating section for selectively accommodating an IC card, a connecting section provided at one end of the housing member and connected to a signal input/output section of an apparatus to which the IC card is electrically connected, and a contact terminal, having a pad portion to be electrically connected to the signal input/output section at one end thereof and a contact portion formed contiguous to the pad portion to be electrically connected to an electrode of the IC card at the other end thereof disposed in the accommodating section.

As apparent from the above description, since the inventive IC card-connecting adapter has the connecting section provided at one end of the housing member and connected to the signal input/output section of the apparatus to which the IC card is electrically connected and the pad portion to be electrically connected to the signal input/output section at the one end, and has the contact portion formed contiguous to the pad portion to be electrically connected to the electrode of the IC card at the other end contiguous to the pad portion and disposed in the accommodating section, the signal input/output section of the apparatus is electrically connected to the electrode section of the IC card by the contact terminal, whereby it is possible to eliminate the soldering operation from the assembly of the IC card-connecting adapter.

The above and other objects, effects, features and advantages of the present invention will become more apparent from the following description of embodiments thereof taken in conjunction with the accompanying drawings.

### BRIEF DESCRIPTION OF THE DRAWINGS

FIG. 1 an exploded plan view showing a structure of one embodiment of an IC card-connecting adapter according to the present invention;

FIG. 2 is a perspective view illustrating an appearance of the embodiment of the inventive IC card-connecting adapter;

FIG. 3 is a perspective view illustrating an appearance of the embodiment of the inventive IC card-connecting adapter, to which the IC card is mounted;

FIG. 4 is a bottom view of the embodiment shown in FIG. 2;

FIG. 5 is a side view of the embodiment shown in FIG. 2;

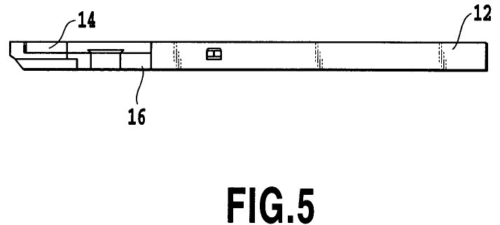

FIG. 6 is a front view of the embodiment shown in FIG. 2 as shown from an open end side thereof;

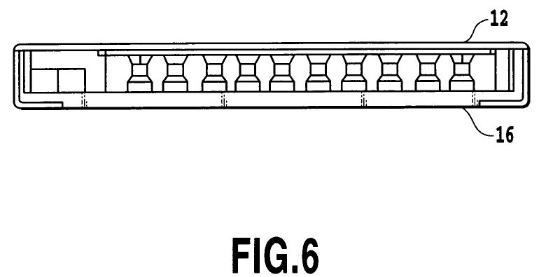

FIG. 7 is a front view of the embodiment shown in FIG. 2 as shown from a connecting end side thereof;

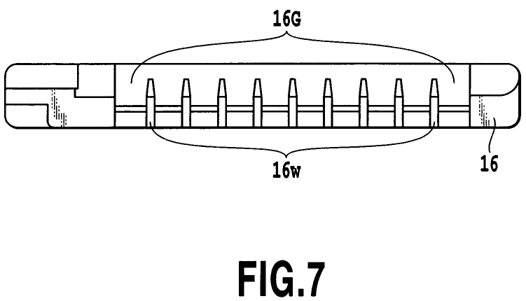

FIG. 8 is a sectional view taken along a line VIII-VIII in FIG. 4;

FIG. 9 is a sectional view taken along a line IX-IX in FIG. 4;

FIG. 10 is a perspective view of a connecting end unit portion used for the embodiment of the inventive IC card-connecting adapter;

FIG. 11 is a perspective view of a connecting end unit portion used for the embodiment of the inventive IC card-connecting adapter shown in FIG. 2;

FIG. 12 is a partially broken enlarged perspective view of a tip of the embodiment shown in FIG. 2;

FIG. 13 is a partially sectional view of the embodiment shown in FIG. 2;

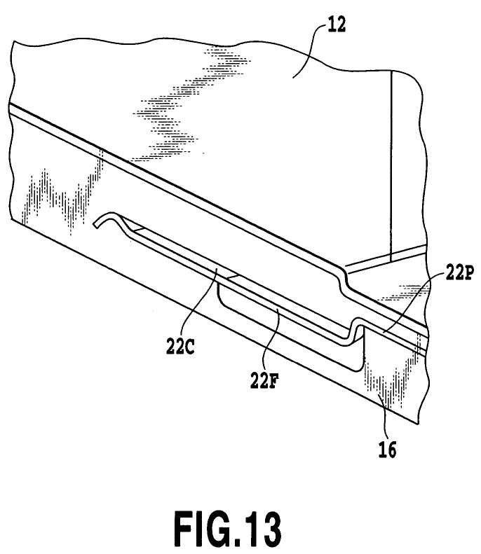

FIG. 14 is a perspective view showing partially a tip of a cover member used in the embodiment shown in FIG. 2;

FIG. 15 is a perspective view showing an example of another cover member used in the embodiment shown in FIG. 2;

FIG. 16 is a perspective view showing a contact terminal in its entirety used in the embodiment shown in FIG. 2; and

FIG. 17 is a plan view of an IC card to be detachably mounted in an IC card-connecting adapter of the embodiment shown in FIG. 2.

### DETAILED DESCRIPTION OF PREFERRED EMBODIMENTS

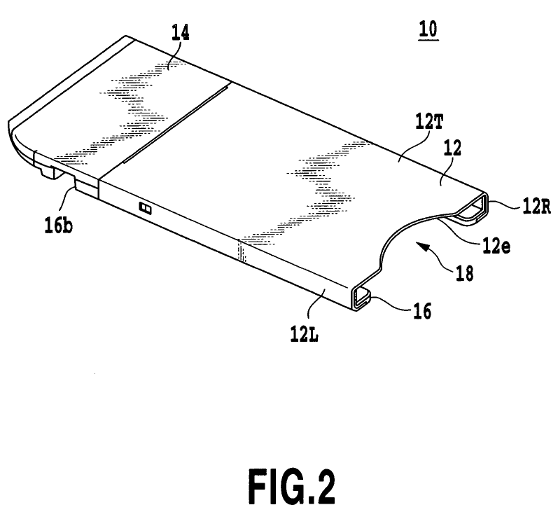

FIG. 2 illustrates an appearance of one embodiment of an IC card-connecting adapter according to the present invention.

As shown in FIG. 2, an IC card-connecting adapter 10 includes a cover member 12 and a base member 16 as a housing member and a connecting end unit portion 14 as a connecting section connected to both of the cover member 12 and the base member 16. Accordingly, a card accommodating section 18 for accommodating an IC card 20 described later is formed between the cover member 12 and the base member 16.

An outer dimension (mm) of the IC card-connecting adapter 10 is equal to an outer dimension of the conventional MEMORYSTICK (trademark), for example, having a thickness of 2.8 mm, a width of 21.5 mm and a total length of approximately 50 mm.

The IC card-connecting adapter 10 electrically connects an electrode section of the detachably accommodated IC card 20 directly or indirectly via a predetermined card connector to a connecting terminal section of a signal-input/output wiring board disposed within a predetermined electronic apparatus. Such an existing card connector (not shown) is incorporated in the interior of the electronic apparatus such as a portable telephone, a telephone, PDA or a camera.

As shown in FIG. 2, the card accommodating section 18 for accommodating the IC card 20 has an opening at one end thereof for allowing the IC card 20 to pass therethrough during the attachment/detachment of the IC card 20.

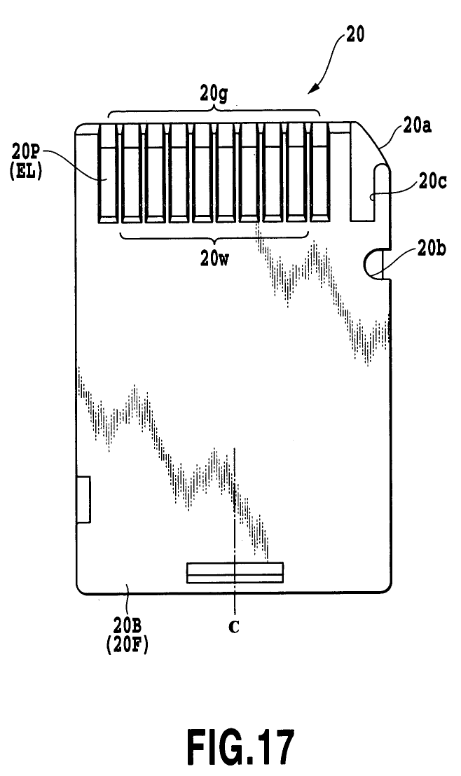

The accommodated IC card 20 is, for example, a MEMORYSTICK DUO (trademark) which is a plate type elongate memory card and, as shown in FIG. 17, has a front surface 20F and a rear surface 20B opposite to each other. Also, the IC card 20 has a chamfered portion 20a at a corner of a tip thereof. An outer dimension (mm) of the IC card 20 is smaller than that of the known MEMORYSTICK (trademark), and, for example, has a width of 20 mm×a thickness of 1.6 mm×a length of 31 mm.

On the rear surface 20B of the IC card 20, a relatively shallow recess 20b is formed in an area adjacent to the chamfered portion 20a. Also, there is a recess 20c formed thinner than the other portion in an area corresponding to the chamfered portion 20a and adjacent to the recess 20b for the purpose of avoiding the interference with a protrusion of the base member 16 not shown.

At a tip of the rear surface 20B of the IC card 20, a plurality of recesses 20g are arranged generally in parallel to a longer edge of the card at a position apart from the recess 20c toward a center line of the card. On bottom surfaces of these recesses 20g, there are contact pads 20p, respectively, as an electrode section. A structure of the contact pads 20p is, for example, of ten-pin system. The every adjacent recesses 20g are sectioned at an equal pitch by an elongate partition wall 20w having a predetermined height lower than a plate thickness of the IC card 20. Accordingly, a group of electrodes EL consisting of the plurality of contact pads 20p are formed on the rear surface 20B of the IC card 20 at a position deviated from a center line C in FIG. 17 in one direction. The contact pads 20p located at either of end positions of the arrangement are used, for example, for a ground line, respectively.

The cover member 12 is made of electro-conductive material such as a surface-treated thin stainless steel sheet to comprise a flat portion 12T forming an upper part of the card accommodating section 18, and side wall portions 12R and 12L contiguous to widthwise opposite ends of the flat portion 12T, respectively, and coupled to the base member 16 as shown in FIG. 2.

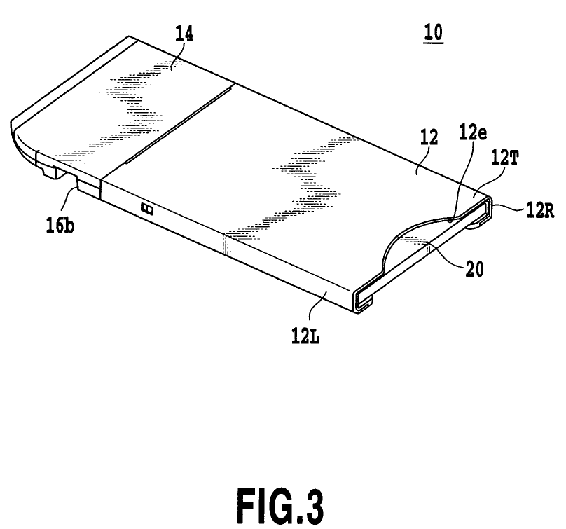

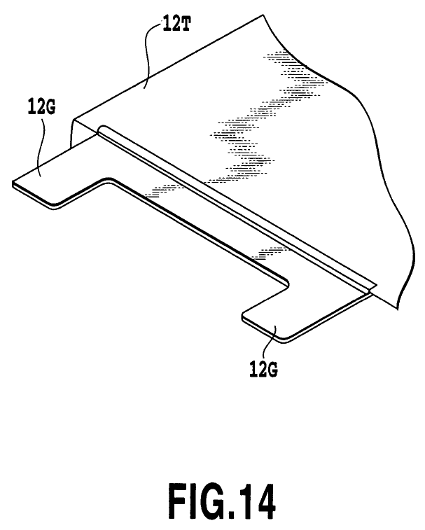

At an end of the flat portion 12T on the above-mentioned opening side, an arcuate portion 12e cut deeply is formed. As shown in FIG. 3, the arcuate portion 12e is provided for facilitating the attachment/detachment of the IC card 20. On the other hand, a pair of ground pieces 12G arranged at a predetermined distance between them are formed integral with each other in a common plane at an end of the flat portion 12T opposite to the arcuate portion 12e, as shown in FIG. 14. A rectangular tip of the ground piece 12G is projected from the end of the flat portion 12T. The respective ground piece 12G is electrically connected to a ground contact terminal described later.

The ends of the side wall portions 12R and 12L are bent to encircle part of a side surface and a bottom surface of the base member 16.

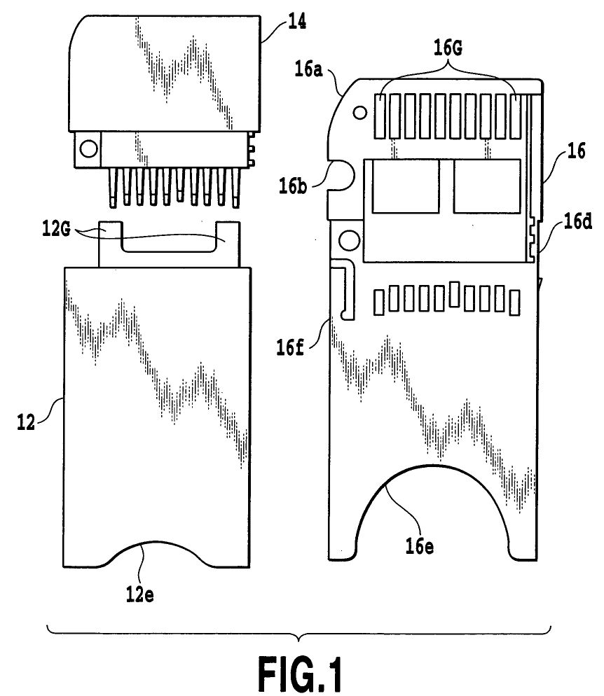

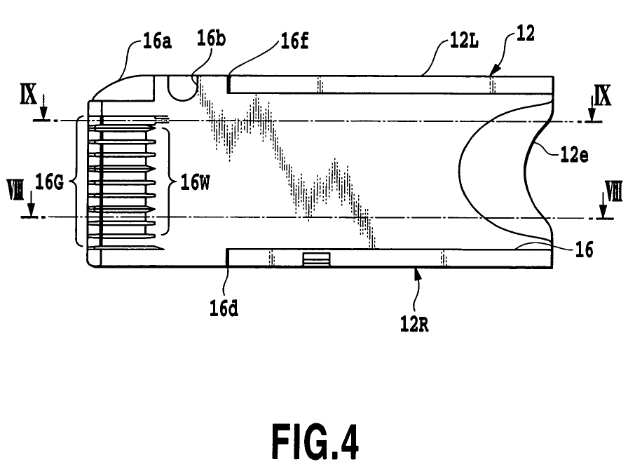

As shown in FIGS. 1 and 4, the base member 16 is molded of resinous material to be a thin integral sheet forming a lower part of the card accommodating section 18. In a portion of the base member 16 opposite to the arcuate portion 12e of the cover member 12, an arcuate portion 16e having a radius of curvature larger than a radius of curvature of the arcuate portion 12e is formed. On the other hand, in a portion of the base member 16 opposite to a connecting end unit portion 14 described later, a plurality of (for example, ten slits) slits 16G are arranged in one row at a predetermined pitch in the widthwise direction in correspondence to contact pads described later, respectively. The adjacent slits 16G are sectioned by a partitioning wall 16w. A curved chamfered portion 16a is formed at a corner at the slits 16G-side end of the base member 16. An arcuate notch portion 16b is formed adjacent to the chamfered portion 16a. As shown in FIG. 4, relatively shallow recesses 16d and 16f are formed in both side surface areas and bottom surface areas of the outer circumference of the base member 16. The recesses 16d and 16f are engaged with the side wall portions 12R and 12L of the cover member 12, respectively.

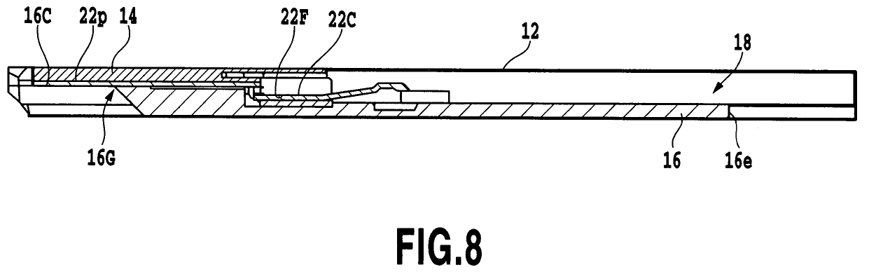

In a portion of the base member 16 in which the slits 16G are provided, a recess 16C is formed on the side on which the connecting end unit portion 14 is provided, as shown in FIG. 8.

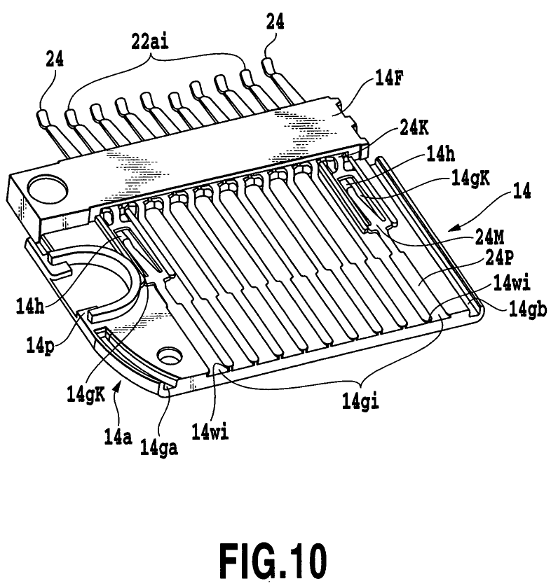

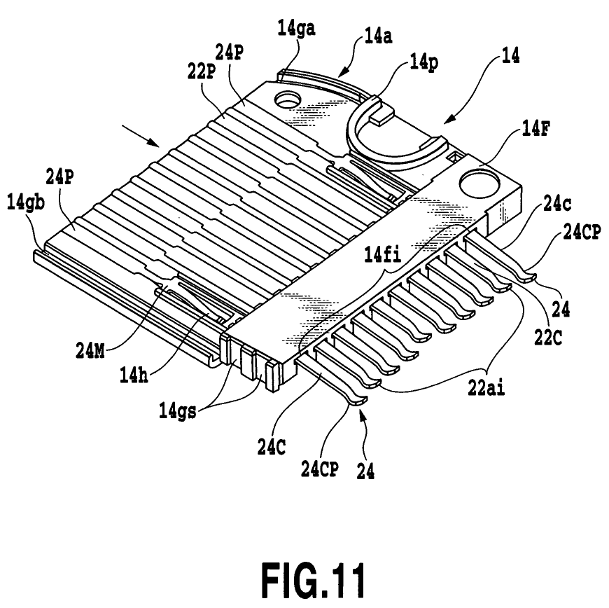

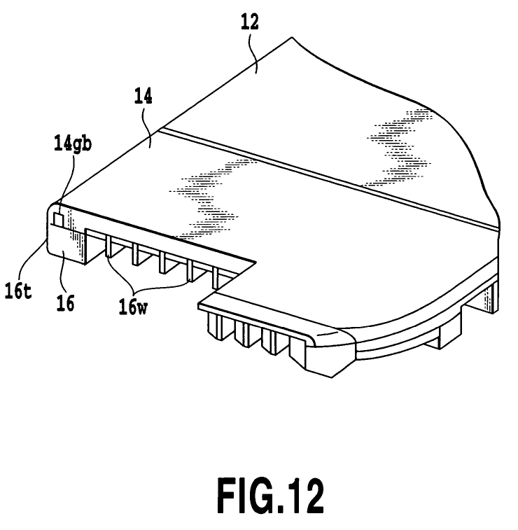

The connecting end unit portion 14 disposed in the recess 16C and coupled thereto has a chamfered portion 14a corresponding to the chamfered portion 16a of the base member 16 to be coupled thereto at a corner of one end thereof as shown in FIGS. 10 and 11. There is a groove 14ga having a predetermined length on the inner side of the outer circumference of the chamfered portion 14a, to be engaged with a protrusion not shown of the base member 16. A U-shaped protrusion 14P corresponding to the notch portion 16b of the base member 16 is formed adjacent to the groove 14ga on the inner surface. Further, as shown in FIGS. 11 and 12, on the inner side of the outer circumference of the connecting end unit portion 14 opposite to the protrusion 14P and the groove 14ga while interposing a group of contact terminals described later between the both, there is a groove 14gb along a side thereof, which has a predetermined length and is engageable with the protrusion 16t of the base member 16. The protrusion 16t and the groove 14gb are bonded together, for example, by the ultrasonic welding. The above-mentioned protrusion of the base member 16 and the groove 14ga are also bonded together in a similar manner by the ultrasonic welding. Accordingly, the rigidity of the bonded portion becomes higher in comparison with a case wherein there is none of such a protrusion and a groove.

As shown in FIG. 10 and 11, a plurality of grooves 14gi (i=1 to 10) are formed in a central area of the inner circumferential surface of the connecting end unit portion 14 between the protrusion 14P and the groove 14gb of the connecting end unit portion 14, to receive contact pads of a group of contact terminals described later.

The groove 14gi is a relatively shallow groove a generally rectangular shaped in cross section opened upward and at one end of the connecting end unit portion 14. Every adjacent grooves 14gi are sectioned by a partitioning wall 14wi (i=1 to 9) having a cross-section of a generally T-shape. In an intermediate portion of the groove 14gi disposed at either of the ends among the plurality of grooves 14gi, a through-hole 14h is formed. On the peripheral edge of the respective through-hole 14h, a groove 14gk is formed, into which is press-fit a contact portion of the contact terminal described later.

As shown in FIG. 10, there is a contact supporting member 14F in the other end portion of the group of grooves 14gi of the connecting end unit portion 14, for supporting a stationary portion of the group of contact terminals.

The contact supporting member 14F has a predetermined width and extends at the other end of the connecting end unit portion 14 in the widthwise direction thereof. As shown in FIG. 11, grooves 14fi (i=1 to 10) corresponding to the grooves 14gi, respectively, extends generally parallel to each other along a side surface of the connecting end unit portion 14. The stationary portion of the respective contact terminal is press-fit into the respective groove 14fi. As shown in FIG. 11. On one side surface of the contact supporting member 14F, there are a plurality of grooves 14gs engageable with an engagement portion not shown of the base member 16.

The group of contact terminals include ground contact terminals 24 for electrically grounding the contact pads 20p disposed at both ends of the IC card 20 and contact terminals 22ai (i=1 to 8) for electrically connecting the other contact pads 20p of the IC card 20.

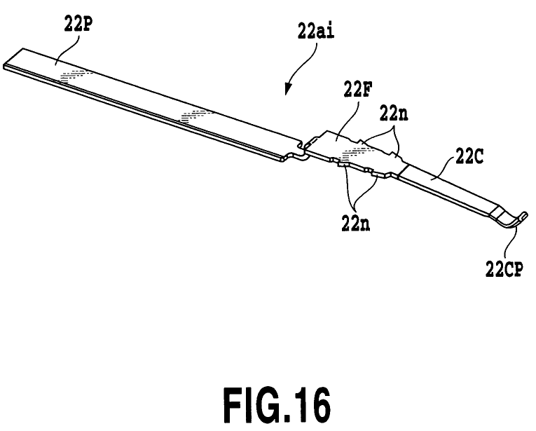

As shown in FIG. 16, the contact terminal 22ai is made of thin metallic sheet material such as a phosphor bronze sheet and includes a contact pad portion 22P electrically connected to a signal input/output section of the connected electronic apparatus, a card-connecting end portion 22C having a contact portion 22CP to be brought into contact and electrically connected with the above-mentioned contact pad 20p of the IC card 20 and a stationary portion 22F for coupling the contact pad portion 22P with the card-connecting end portion 22C.

The contact pad portion 22P is of a generally rectangular shape having a predetermined width, and opposed to the slit 16G of the base member 16 while being communicated therewith, as shown in FIG. 8. The stationary portion 22F is continued to one end of the contact pad portion 22P via a relatively thin curved portion, and is provided with nibs 22n to be engaged with the peripheral edges of the above-mentioned groove. A width of the curved portion is smaller than that of the contact pad portion 22P. The card-connecting end portion 22C has resilient and coupled in integral with an end of the stationary portion 22F. Accordingly, in the contact terminal 22ai, the contact pad portion 22P is integral with the card-connecting end portion 22C without the intervention of a wiring board or others. The respective contact terminal 22ai is easily mounted to the base member 16 by press-fitting the contact terminal 22ai into the grooves 14gi and 14fi from the card-connecting end portion 22C side in the direction indicated by an arrow in FIG. 11.

On the other hand, as shown in FIGS. 10 and 11, the contact terminal 24 is made of thin metallic sheet material such as a thin phosphor bronze sheet, and includes a contact pad portion 24P electrically connected to a ground line of the connected electronic apparatus, a card-connecting end portion 24C having contact portion 24CP to be touched and electrically connected to the above-mentioned ground contact pad 20p of the IC card 20, and a stationary portion for coupling the contact pad portion 24P with the card-connecting end portion 24C.

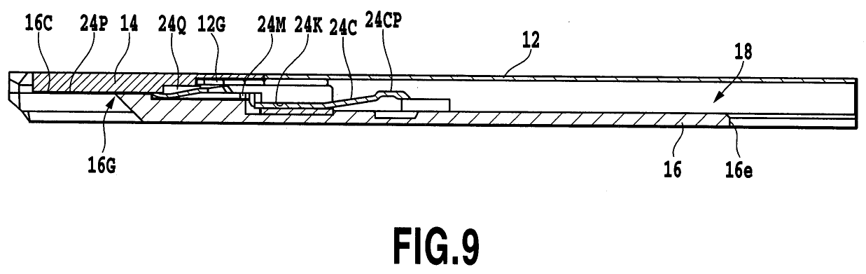

The contact pad portion 24P is of a generally rectangular shape having a predetermined width, and opposed to the slit 16G of base member 16 and communicated thereto, as shown in FIG. 9, The above-mentioned stationary portion includes a frame-like intermediate contact portion 24M contiguous to one end of the contact pad portion 24P via a relatively thin coupling portion, and an enlarged portion 24K coupled to one end of the intermediate contact portion 24M via an elongate curved portion.

The intermediate contact portion 24M has an contact piece 24Q projected into the through-hole 14h of the connecting end unit portion 14. One end of the resilient contact piece 24Q is formed in integral with a frame-like portion. The other end of the contact piece 24Q is brought into contact with the ground piece 12G of the cover member 12 at a predetermined pressure as shown in FIG. 9.

The enlarged portion 24K is coupled to the intermediate contact portion 24M by a curved portion. A width of the curved portion is smaller than those of the contact pad portion 24P and the intermediate contact section 24M.

The enlarged portion 24K has nibs engageable with the peripheral edges of the above-mentioned groove of the contact supporting member 14F. The card-connecting end portion 24C has the elasticity and integrally coupled to one end of the enlarged portion 24K.

Accordingly, when the ground line of the electronic apparatus is grounded, the connected cover member 12 and the ground contact pad 20p of the IC card 20 are assuredly grounded via the contact terminal 24 and the cover member 12. As a result, lo static electricity generated in the IC card-connecting adapter 10 is removed.

In this regard, while the resilient contact piece 24Q of the contact terminal 24 is brought into contact with the ground piece 12G of the cover member 12 at the predetermined pressure in the above embodiment, the present invention should not be limited thereto.

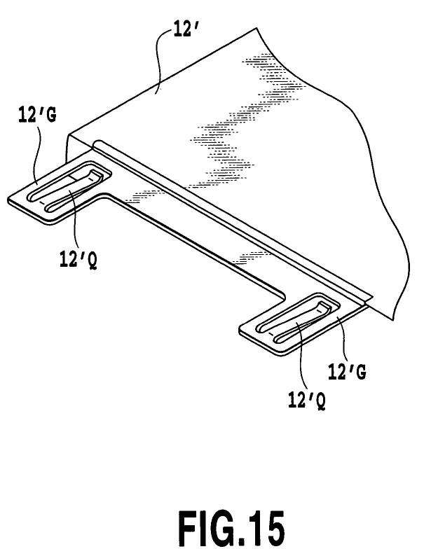

For example, as shown in FIG. 15, a ground piece 12′G of a cover member 12′ may have a resiliently deformable contact piece 12′Q, while a portion of the ground piece 12′G corresponding thereto may have a contact surface to be in contact with the ground piece 12′G at a predetermined pressure.

In this structure, during the assembly of the IC card-connecting adapter 10, the base member 16 is initially fitted to an interior of the cover member 12 so that the side surface of the former is inserted into the inner surface of the cover member 12 by a predetermined length, and thereafter, the connecting end unit portion 14 assembled with the contact terminals 24 and the contact terminals 22ai is disposed in the recess 16C of the base member 16. At that time, the respective grooves 14ga, 14gb and 14gs are engaged with protrusions formed on the peripheral edges of the recess 16C in the base member 16, and the contact piece 24Q of the contact terminal 24 is brought into contact with the ground piece 12G of the cover member 12 at a predetermined pressure.

Then, the connecting end unit portion 14 and the base member 16 are welded together at the predetermined positions thereof . Thus, the assembly of the IC card-connecting adapter 10 is completed.

When the assembled IC card-connecting adapter 10 is used, the IC card 20 is inserted into the accommodating section 18 until the end of the card coincides with the open end of the latter as shown in FIG. 3.

The present invention has been described in detail with respect to preferred embodiments, and it will now be apparent from the foregoing to those skilled in the art that changes and modifications may be made without departing from the invention in its broader aspect, and it is the intention, therefore, in the apparent claims to cover all such changes and modifications as fall within the true spirit of the invention.

1. An IC card-connecting adapter comprising:
a housing member forming an accommodating section for detachably accommodating an IC card,
a connecting section provided at one end of said housing member and connected to a signal input/output section of an apparatus to which said IC card is electrically connected, and
a contact terminal, having a pad portion to be electrically connected to said signal input/output section at one end thereof and a contact portion formed contiguous to said pad portion to be electrically connected to an electrode of said IC card at the other end thereof disposed in the said accommodating section.

2. An IC card-connecting adapter as claimed in claim 1, wherein a plurality of contact terminals are provided in correspondence to the respective electrodes of said IC card, and at least one of said contact terminals is provided with a ground contact portion to be electrically connected to said housing member in an intermediate area between said contact portion and said pad portion.

3. An IC card-connecting adapter as claimed in claim 1, wherein said connecting section has a support section for supporting said contact terminal and a groove into which said pad section of said contact terminal is inserted.

4. An IC card-connecting adapter as claimed in claim 2, wherein said ground contact portion is brought into contact with a ground piece provided integral with an end of said housing member.

5. An IC card-connecting adapter as claimed in claim 1, wherein said housing member has a resiliently deformable contact piece brought into contact with a portion of said contact terminal between said contact portion and said pad portion.

6. An IC card-connecting adapter as claimed in claim 2, wherein said contact terminal having said ground contact portion is arranged at either of ends of the arrangement of said contact terminals.

7. An IC card-connecting adapter as claimed in claim 2, wherein said connecting section forms an connecting end unit portion including said plurality of contact terminals.
